(19) United States
(12) Patent Application Publication
(10) Pub. No.: US 2020/0068754 A1
(43) Pub. Date: Feb. 27, 2020

(54) METHOD OF ARRANGING A HUGE AMOUNT OF CHIPS

(71) Applicant: Chung-Lin WANG, Hsinchu City (TW)

(72) Inventor: Chung-Lin WANG, Hsinchu City (TW)

(21) Appl. No.: 16/548,715

(22) Filed: Aug. 22, 2019

(30) Foreign Application Priority Data
Aug. 24, 2018 (TW) 107129635

(51) Int. Cl. H05K 13/02; H01L 33/00; H05K 13/04

(52) U.S. Cl. CPC H05K 13/028; H05K 13/0469; H01L 33/0095

(57) ABSTRACT

The present invention provides a method of arranging a huge amount of chips, comprising the sequential steps: a providing step of providing a substrate and a plurality of chips; a spreading step of spreading a plurality of chips on the surface of the substrate; a tilting step of tilting the substrate by an angle to slide down the plurality of chips along the surface of the substrate so that the trapping stoppers trap the plurality of chips respectively in such a manner that the blocked chips are placed in the chip placing areas respectively; an adhering step of adhering, onto the chip placing areas, the chips with the working surface upward; and a removing step of removing, from the substrate, the chips which are not adhered onto the chip placing areas. A huge number of chips can be transferred efficiently by the method of the present invention.

### FIELD OF THE INVENTION

The present invention relates to a method of arranging chips, and particularly relates to a method of arranging a huge amount of chips.

### BACKGROUND OF THE INVENTION

With the advancement of technology, the micro light-emitting diode display is drawing attention in the market. The micro light-emitting diode display consists of a circuit substrate and a large number of chips arranged orderly and precisely on it.

However, since the micro light-emitting diode displaying device requires millions of chips or even tens of millions of chips, the conventional manufacturing process, i.e., moving chips with a robotic arm, must take time and therefore, production efficiency is low and cost is high.

### SUMMARY OF THE INVENTION

Accordingly, in order to solve the above problems, an objective of the present invention is to provide a method of arranging a huge amount of chips.

In order to overcome the technical problems in prior art, the present invention provides a method of arranging a huge amount of chips, comprising the following sequential steps: a providing step of providing a substrate and a plurality of chips, a surface of the substrate being provided with a plurality of trapping stoppers protruding therefrom, the trapping stoppers being provided to trap chips so that each chip is placed in a chip placing area of one trapping stopper respectively, and each chip having a working surface and an adhesive surface, each adhesive surface being provided with an environmentally reacting adhesive element; a spreading step of spreading a plurality of chips on the surface of the substrate; a tilting step of tilting the substrate by an angle to slide down the plurality of chips along the surface of the substrate so that the trapping stoppers trap the plurality of chips respectively in such a manner that the blocked chips are placed in the chip placing areas respectively; an adhering step of adhering, onto the chip placing areas, the chips with the working surface upward; and a removing step of removing, from the substrate, the chips which are not adhered onto the chip placing areas.

In one embodiment of the invention, a method of arranging a huge amount of chips is provided, wherein the chip provided in the providing step is 4-fold rotational symmetry.

In one embodiment of the invention, a method of arranging a huge amount of chips is provided, wherein in the providing step, the trapping stopper on the substrate is in shape correspondence with an outer contour of the chip.

In one embodiment of the invention, a method of arranging a huge amount of chips is provided, wherein in the providing step, the trapping stopper on the substrate is L-shaped.

In one embodiment of the invention, a method of arranging a huge amount of chips is provided, after the tilting step, further comprising a distributing step of evenly distributing the plurality of chips on the surface of the substrate by applying an external force thereto.

In one embodiment of the invention, a method of arranging a huge amount of chips is provided, wherein the environmentally reacting adhesive element is a thermally sensitive adhesive element, and the adhering step includes: a heating step of heating the surface of the substrate so that the chips with the thermally sensitive adhesive element contacting the substrate are adhered onto the chip placing areas; and a cooling step of cooling down the surface of the substrate to cool down the chips on the substrate.

In one embodiment of the invention, a method of arranging a huge amount of chips is provided, wherein the environmentally sensitive adhesive element is a light-sensitive adhesive element, the substrate is light-transparent, and the adhering step includes an exposing step of exposing the substrate by light so that the chips with the light-sensitive adhesive element contacting the substrate are adhered onto the chip placing areas.

In one embodiment of the invention, a method of arranging a huge amount of chips is provided, wherein in the removing step, the chips which are not adhered onto the chip placing areas are removed by a suction nozzle.

In one embodiment of the invention, a method of arranging a huge amount of chips is provided, after the removing step, further comprising a repeating step of repeating the spreading step, the tilting step, the adhering step and the removing step.

In one embodiment of the invention, a method of arranging a huge amount of chips is provided, after the repeating step, further comprising a filling step of filling the chips to the empty chip placing areas.

Through the technical means adopted by the present invention, a huge number of chips can be transferred on the substrate with high efficiency, simple steps and low cost, so that the production cost of the product is greatly reduced.

The specific embodiments of the present invention will be further described by the following embodiments and the accompanying drawings.

### BRIEF DESCRIPTION OF THE DRAWINGS

FIG. 1 is a flow chart showing a method of arranging a huge amount of chips according to the first embodiment of the present invention.

FIG. 2 is a schematic view showing a substrate according to the embodiment of the present invention.

FIG. 3A is a schematic view showing a working surface of the chip according to the first embodiment of the present invention.

FIG. 3B is a schematic view showing an adhering surface of the chip according to the first embodiment of the present invention.

FIG. 3C is a schematic view showing the working surface of the chip according to the third embodiment of the present invention.

FIG. 4 is a schematic diagram showing the tilting step according to the embodiment of the present invention.

FIG. 5 is a schematic view showing wiring according to the third embodiment of the present invention.

FIG. 6 is a flow chart showing a method of arranging a huge amount of chips according to the second embodiment of the present invention.

### DETAILED DESCRIPTION OF THE PREFERRED EMBODIMENTS

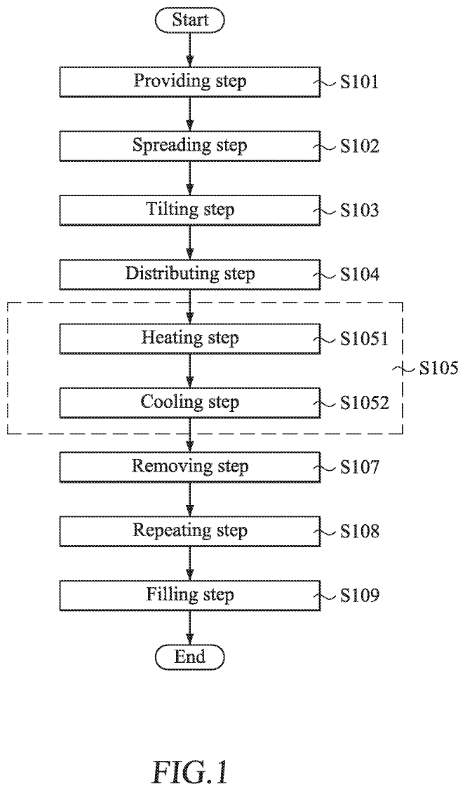

The preferred embodiments of the present invention are described in detail below with reference to FIGS. 1 to 6. The description is used for explaining the embodiments of the present invention only, but not limiting the scope of the claims.

As shown in FIG. 1, a method of arranging a huge amount of chips according to the first embodiment of the present invention includes the following sequential steps: a providing step S101, a spreading step S102, a tilting step S103, a distributing step S104, an adhering step S105, a removing step S107, a repeating step S108 and a filling step S109.

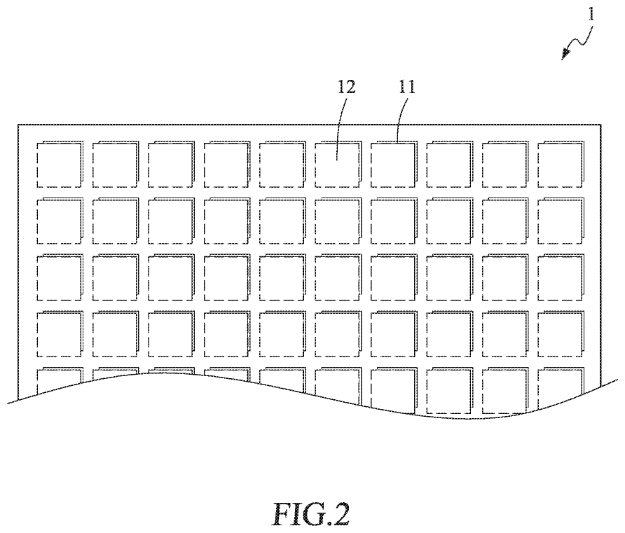

In the providing step S101, a substrate 1 (as shown in FIG. 2) and a plurality of chips 2 are provided. A surface of the substrate 1 is provided with a plurality of trapping stoppers 11. Each of the trapping stoppers 11 tries to trap one chip 2 so that each chip 2 is placed in a chip placing area 12 of one trapping stopper 11 respectively. In the present embodiment, the chip 2 is an LED microchip, but the invention is not limited thereto. In the present embodiment, the trapping stopper 11 on the substrate 1 is in shape correspondence with an outer contour of the chip 2. Furthermore, the trapping stopper 11 on the substrate 1 is L-shaped, but the present invention is not limited thereto. The trapping stopper 11 may be other shapes such as an M-shape, a square shape, or other shapes in shape correspondence with the outer contour of the chip 2.

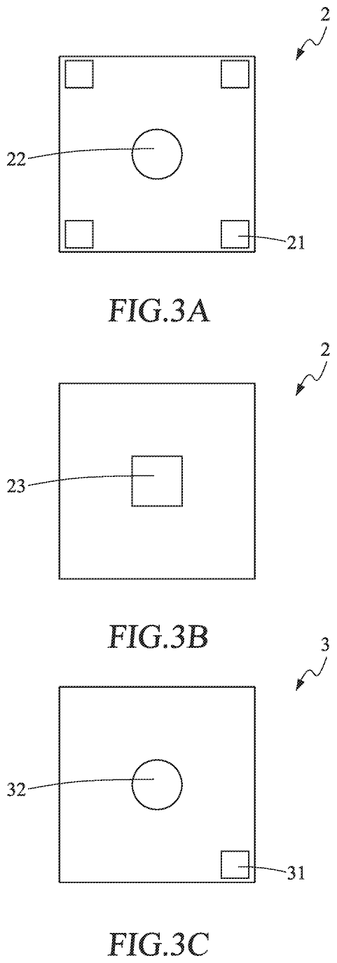

Each chip 2 is provided with a working surface and an adhesive surface. The adhesive surface is used for adhering the chip 2 onto the surface of the substrate 1. The working surface and the adhesive surface are respectively provided on the opposite surfaces of the chip 2. In this embodiment, the working surface of the chip 2 can emit light, but the invention is not limited thereto, and the working surface could provide any other functions. FIGS. 3A and 3B respectively show the working surface and the adhesive surface of the chip 2. In FIG. 3A, the working surface of each chip 2 is provided with a first electrical contact 21 and a second electrical contact 22. In FIG. 3B, the adhesive surface of each chip 2 is provided with an environmentally reacting adhesive element 23, for example, a thermally sensitive adhesive element, such as a hot melt adhesive, whose adhesiveness varies significantly according to the environmental change, e.g., temperature change. Alternatively, the environmentally reacting adhesive element 23 could be a light-sensitive adhesive element, such as an ultraviolet film, whose adhesiveness varies significantly according to environmental change e.g., light exposure. The environmentally reacting adhesive element 23 is in the form of a thin layer or a granule. In the first embodiment of the present invention, the thermally sensitive adhesive element is taken as an example. In this embodiment, the outer contour of the chip 2 is a square shape, but the present invention is not limited thereto, and the outer contour of the chip 2 could be any other shapes. Furthermore, in the embodiment, the chip 2 is 4-fold rotational symmetry, that is, the pattern of the chip looks the same by 90 degree rotation. The second electrical contact 22 is disposed at the center of the working surface of the chip 2. There are four first electrical contacts 21 respectively located at four corners of the working surface of the chip 2. However, the present invention is not limited thereto. In the third embodiment, as shown in FIG. 3C, the first electrical contact 31 of the working surface of the chip 3 is located only at one corner of the working surface of the chip 3.

In the first embodiment of the present invention, after the providing step S101, the spreading step S102 of spreading the plurality of chips 2 on the surface of the substrate 1 is performed. The spreading step S102 is to spread a large number of chips 2 on the surface of the substrate 1. In the present embodiment, the plurality of chips 2 are simply and evenly spread on the surface of the substrate 1. However, the present invention is not limited thereto, and a large number of chips 2 may be spread to the surface of the substrate 1 by other ways.

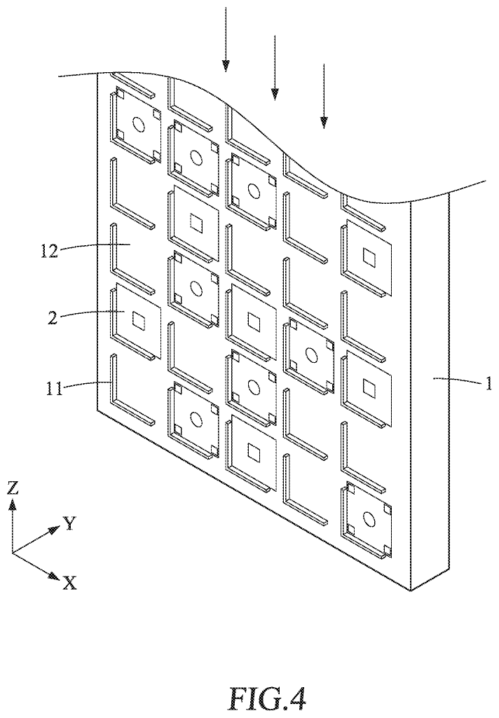

After the spreading step S102, the tilting step S103, as shown in FIG. 4, of tilting the substrate 1 by an angle to slide down the plurality of chips 2 along the surface of the substrate 1 is performed so that the trapping stoppers 11 trap the plurality of chips 2 respectively in such a manner that the trapped chips 2 are placed in the chip placing areas 12 respectively. In this step, the angle is generally related to the shape of the trapping stopper 11 and the stopping direction, so as to stop, by the trapping stopper 11, the chip 2 sliding down by gravity in such a manner that the chip 2 is placed in the chip placing area 12 defined by the trapping stopper 11. Adjusting the tilting angle and the tilting direction again and again to place as many chips 2 as possible in the trapping stoppers 11, respectively can be performed, too. In this embodiment, the tilting step S103 is accompanied with vibration.

After the tilting step S103, the distributing step S104 of evenly distributing the plurality of chips 2 on the surface of the substrate 1 is performed by applying an external force thereto. For example, the plurality of chips 2 can be evenly distributed on the surface of the substrate 1 by using physical means such as sound wave oscillating, blowing, or sweeping.

In FIG. 4, after the tilting step S103 and the distributing step S104 have been performed, in the chip placing area 12, one of three situations may occur: (i) the working surface of the chip 2 faces upward; (ii) the adhering surface of the chip 2 faces upward; or (ii) there is no chip 2. Moreover, since the chip 2 is 4-fold rotational symmetry, the orientation of the chip 2 in the chip placing area 12 is the same.

After the tilting step S103 and the distributing step S104, the adhering step S105 is performed. The plurality of chips 2 with the working surface upward are adhered onto the chip placing areas 12 by the environmentally reacting adhesive elements 23. In the first embodiment of the present invention, the adhering step S105 includes a heating step S1051 and a cooling step S1052. In the heating step S1051, the surface of the substrate 1 is heated so that the chips with the environmentally reacting adhesive elements 23 (thermally sensitive adhesive elements) contacting the substrate are adhered onto the chip placing areas 12. On the contrary, the chips with the adhesive surface upward are not adhered onto the chip placing areas 12 even though the environmentally reacting adhesive elements 23 are heated up.

After the heating step S1051, the cooling step S1052 is performed. Cooling down the surface of the substrate 1 to cool down the environmentally reacting adhesive elements 23 of the chips 2 on the substrate 1. Meanwhile, the chips with the working surface upward are firmly adhered onto the chip placing areas 12, and the chips with the adhering surfaces upward are not adhered onto the substrate 1. Those that are not adhered onto the substrate 1 can be recycled and be reused.

After the cooling step S1052, the removing step S107 is performed. The chips 2 which are not adhered onto the chip placing areas 12 are removed from the substrate 1. In this embodiment, the chips 2 which are not adhered onto the chip placing areas 12 are sucked away by a suction nozzle.

Furthermore, in this embodiment, after the removing step S107, the method further includes a repeating step S108 of repeating the spreading step S102, the tilting step S103, the distributing step S104, the adhering step S105, the removing step S107, etc., so as to reduce the proportion of empty chip placing areas 12.

Furthermore, in this embodiment, after the repeating step S108, the method further includes a filling step S109 of adhering the chips onto the empty chip placing areas 12. In this step, the empty chip placing areas 12 are typically found and positioned by Automated Optical Inspection. In one embodiment, the chips 2 are filled by using a suction nozzle. However, the invention is not limited thereto, and the chips 2 may be filled by other means. For example, the chips 2 can be placed and be adhered onto the empty chip placing areas 12 by an electrostatic force.

It should be noted that, in the embodiment, the chip 2 is 4-fold rotational symmetry, so the relative position between the first electrical contact 21, the second electrical contact 22, and the corresponding trapping stopper 11 corresponds to each other all the time, and then the wiring process can be easily performed.

With the method of arranging a huge amount of chips described in the above embodiment of the present invention, a large number of chips 2 can be transferred to the substrate 1 with high efficiency, simple steps, and low cost.

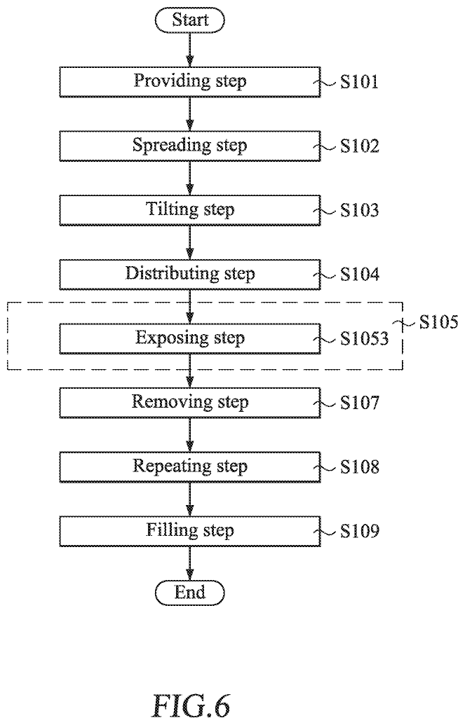

Furthermore, the second embodiment of the present invention is provided. In the second embodiment, the difference between the first embodiment and the second embodiment is that the environmentally reacting adhesive element 23 is a light-sensitive adhesive element, and the substrate 1 is light-transparent. As shown in FIG. 6, in the second embodiment, the adhering step S105 includes an exposing step S1053. In the exposing step S1053, the substrate 1 is exposed by light. Preferably, the chips with the light-sensitive adhesive elements contacting the substrate are adhered onto the chip placing areas 12 by light exposure from the other surface of the substrate. Next, the removing step S107 is performed to remove the chips 2 which are not adhered onto the substrate 1. The repeating step S108 and the filling step S109 are also performed in the second embodiment.

Furthermore, the present invention provides the third embodiment. In the third embodiment, the chip 3 in FIG. 3C is provided in the providing step S101. Since the working surface of the chip 3 is provided with only one first electrical contact 31, the working area is larger than that of the chip 2. Taking the LED microchip as an example, the chip 3 has a larger light-emitting area than that of the chip 2 and can emit more light.

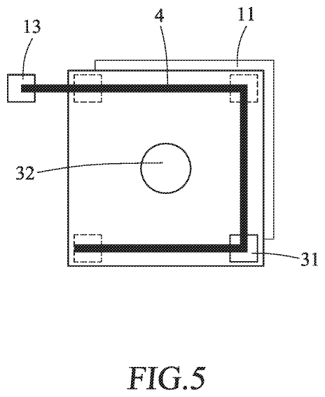

Similarly, the process is performed from the spreading step S102 to the filling step S109. As shown in FIG. 5, since the chip 3 is not 4-fold rotational symmetry, four possible relative positions between the first electrical contact 31 and the trapping stopper 11 appear. Although, the relative position between the first electrical contact 31 and the trapping stopper 11 is not fixed, the substrate contact 13 and all the four possible positions where the first electrical contact 31 may appear still can be connected by the designed wire 4 in the later process.

In summary, with respect to the prior art, the method of arranging a huge amount of chips of the present invention can transfer a large amount of chips with high efficiency so as to increase the assembling speed and reduce cost.

The above description is only an explanation of the preferred embodiments of the present invention. One having ordinary skill in the art can make various modifications according to the above description and the claims defined below. However, those modifications shall still fall within the scope of the present invention.

What is claimed is:

1. A method of arranging a huge amount of chips, comprising the following sequential steps:
a providing step of providing a substrate and a plurality of chips, a surface of the substrate being provided with a plurality of trapping stoppers protruding therefrom, the trapping stoppers being provided to trap chips so that each chip is placed in a chip placing area of one trapping stopper respectively, and each chip having a working surface and an adhesive surface, each adhesive surface being provided with an environmentally reacting adhesive element;
a spreading step of spreading the plurality of chips on the surface of the substrate;
a tilting step of tilting the substrate by an angle to slide down the plurality of chips along the surface of the substrate so that the trapping stoppers trap the plurality of chips respectively in such a manner that the blocked chips are placed in the chip placing areas respectively;
an adhering step of adhering, onto the chip placing areas, the chips with the working surface upward; and
a removing step of removing, from the substrate, the chips which are not adhered onto the chip placing areas.

2. The method as claimed in claim 1, wherein the chip provided in the providing step is 4-fold rotational symmetry.

3. The method as claimed in claim 1, wherein in the providing step, the trapping stopper on the substrate is in shape correspondence with an outer contour of the chip.

4. The method as claimed in claim 1, wherein in the providing step, the trapping stopper on the substrate is L-shaped.

5. The method as claimed in claim 1, after the tilting step, further comprising a distributing step of evenly distributing the plurality of chips on the surface of the substrate by applying an external force thereto.

6. The method as claimed in claim 1, wherein the environmentally reacting adhesive element is a thermally sensitive adhesive element, and the adhering step includes:
a heating step of heating the surface of the substrate so that the chips with the thermally sensitive adhesive element contacting the substrate are adhered onto the chip placing areas; and
a cooling step of cooling down the surface of the substrate to cool down the chips on the substrate.

7. The method as claimed in claim 1, wherein the environmentally sensitive adhesive element is a light-sensitive adhesive element, the substrate is light-transparent, and the adhering step includes an exposing step of exposing the substrate by light so that the chips with the light-sensitive adhesive element contacting the substrate are adhered onto the chip placing areas.

8. The method as claimed in claim 1, wherein in the removing step, the chip which are not adhered onto the chip placing areas are removed by a suction nozzle.

9. The method as claimed in claim 1, after the removing step, further comprising a repeating step of repeating the spreading step, the tilting step, the adhering step and the removing step.

10. The method as claimed in claim 9, after several repeating steps, further comprising a filling step of filling the chips to the empty chip placing areas.
